(19) United States
(12) Patent Application Publication
(10) Pub. No.: US 2016/0133819 A1
(43) Pub. Date: May 12, 2016

(54) Fluorine Containing Low Loss Dielectric Layers for Superconducting Circuits

(71) Applicant: Intermolecular, Inc., San Jose, CA (US)

(72) Inventors: Frank Greer, Pasadena, CA (US); Ashish Bodke, San Jose, CA (US)

(73) Assignee: Intermolecular, Inc., San Jose, CA (US)

(21) Appl. No.: 14/982,285

(22) Filed: Dec. 29, 2015

Related U.S. Application Data
(63) Continuation-in-part of application No. 14/138,909, filed on Dec. 23, 2013.

(51) Int. Cl. H01L 39/02; C23C 16/513; C23C 16/24; H01L 39/24; H01L 39/12

(52) U.S. Cl. CPC H01L 39/025; H01L 39/2416; H01L 39/2493; H01L 39/249; H01L 39/12; C23C 16/24; C23C 16/513

(57) ABSTRACT

Provided are superconducting circuits and methods of forming such circuits. A circuit may include a silicon containing low loss dielectric (LLD) layer formed by fluorine passivation of dangling bonds of silicon atoms in the layer. The LLD layer may be formed from silicon nitride or silicon oxide. For uniform passivation (e.g., uniform distribution of fluorine within the LLD layer), fluorine may be introduced while forming the LLD layer. For example, a fluorine containing precursor may be supplied into a deposition chamber together with a silicon containing precursor. Alternatively, the LLD layer may be formed as a stack of many thin sublayers, and each sublayer may be subjected to individual fluorine passivation. For example, low power plasma treatment or annealing in a fluorine containing environment may be used for this purpose. The concentration of fluorine in the LLD layer may be between about 0.5% atomic and 5% atomic.

### CROSS-REFERENCE TO RELATED APPLICATIONS

This application is a continuation-in-part of U.S. patent application Ser. No. 14/138,909, filed on Dec. 23, 2013, which is herein incorporated by reference for all purposes.

### BACKGROUND

Silicon containing dielectric materials, such as amorphous silicon, silicon oxides, and silicon nitrides, have low costs of fabrication, which makes these dielectric materials attractive for various application, such as dielectrics for superconducting interconnects and planar microwave devices. However, these silicon containing dielectric materials often suffer from quite substantial loss tangent at microwave frequencies (e.g., 3-300 GHz) and longer infrared frequencies (300-1000 GHz), which substantially limit application of these materials in superconducting circuits operating at high frequency. This loss tangent is generally not a concern for conventional circuits, which do not operate at high frequencies and do have power losses associate with high frequencies. The loss tangent is believed to be caused by defects in these silicon containing dielectric materials. The defects frequently form during deposition of these materials, such as due to contaminants, incomplete reaction, weak atomic bonds, and the like. Superconducting circuits as well as high-frequency classical devices (e.g., by reducing signal attenuation, dispersion, and jitter) and quantum devices (e.g., by increasing coherence times for quantum state signals) would greatly benefit from reduction of loss tangent in silicon containing materials. However, most of conventional techniques, such as post-deposition treatment of layers containing these silicon containing materials have not yielded acceptable results.

### SUMMARY

Provided are superconducting circuits and methods of forming such circuits. A circuit may include a silicon containing low loss dielectric (LLD) layer that includes fluorine. More specifically, fluorine may be used to passivate dangling bonds of silicon atoms in the LLD layer and, as a result, substantially reduce loss tangent of this layer. The LLD layer may be formed from silicon nitride or silicon oxide. In order to ensure uniform distribution of fluorine with the LLD layer and uniform passivation of silicon atoms within the layer, fluorine may be introduced while forming the LLD layer. For example, a fluorine containing precursor may be supplied into a deposition chamber together with a silicon containing precursor or, more specifically, while depositing a silicon containing material of the layer. When the silicon containing precursor is silane or another hydrogen containing compound, fluorine may displace any hydrogen residue in the formed layer while forming stronger bonds with silicon atoms than hydrogen would have. Alternatively, the LLD layer may be formed as a stack of many thin sublayers, and each sublayer may be subjected to individual fluorine passivation. For example, low power plasma treatment or thermal annealing in a fluorine containing environment may be used for passivating each individual sublayer.

In some embodiments, a method of forming a superconducting circuit involves providing a metal layer. The metal layer may be a part of Josephson junction, for example. The metal may be niobium, aluminum, tantalum or any other suitable metal, for example, a metal exhibiting superconductivity at set operating conductions. The method may proceed with forming a LLD layer over the metal layer using chemical vapor deposition (CVD). Forming the LLD layer is performed at a temperature of less than 525° C. The LLD layer has a thickness of between about 3,000 Angstroms and 10,000 Angstroms. The LLD layer includes one of silicon nitride or silicon oxide or, more specifically, silicon oxide. The LLD layer may also include fluorine evenly distributed throughout the LLD layer. The concentration of fluorine in the LLD layer is between about 0.5% atomic and 5% atomic or, more specifically, between about 0.5% atomic and 5% atomic or even between about 0.5% atomic and 5% atomic. In some embodiments, the method also involves thermal annealing the LLD layer.

In some embodiments, forming the LLD layer involves flowing a silicon containing precursor into a deposition chamber and flowing a fluorine containing precursor into deposition chamber at same time with the silicon containing precursor. The silicon containing precursor may include one of disilane or trisilane. The fluorine containing precursor may include one of nitrogen trifluoride, hydrogen fluoride, xenon difluoride, or silicon tetrafluoride.

Both types of precursors (i.e., the silicon containing precursor and the fluorine containing precursor) may be flowed at all times during deposition of the LLD layer. In some embodiments, the silicon containing precursor may be flowed at a constant flow rate while forming the LLD layer. The fluorine containing precursor may also be flowed at a constant flow rate while forming the LLD layer. Alternatively, the silicon containing precursor may be flowed at a constant flow rate while forming the LLD layer, while the fluorine containing precursor may be flowed in a series of pulses. Furthermore, the flow of the silicon containing precursor may be suspended while forming the fluorine containing precursor into the deposition chamber.

The CVD used to form the LLD layer may be plasma enhanced chemical vapor deposition (PECVD), in which plasma is used to activated the precursors and improve reaction kinetics. Alternatively, the CVD used to form the LLD layer may be a thermal chemical vapor deposition, in which the temperature of the substrate is used to control the kinetics of the deposition reaction.

In some embodiments, forming the LLD layer involves: (a) depositing a silicon containing sublayer of the LLD layer, (b) performing fluorine passivation of the silicon containing sublayer, and (c) repeating (a) and (b) until reaching a target thickness of the LLD layer. Each of the silicon containing sublayer has a thickness of less than 500 Angstroms or even less than 100 Angstroms. The fluorine passivation may involve one of plasma treatment (e.g., with plasma containing fluorine radicals) or thermal annealing (e.g., in a fluorine containing environment). In some embodiments, the number of silicon dangling bonds decrease in the silicon containing layer while performing the fluorine passivation.

Provided also is a superconducting circuit including a metal layer. The metal layer may be a part of Josephson junction, for example. The superconducting circuit may also include an LLD layer disposed over the metal layer. The LLD layer may include one of silicon nitride or silicon oxide. In some embodiments, the LLD layer includes silicon oxide. The LLD layer may also include fluorine evenly distributed throughout the LLD layer. The concentration of fluorine in the LLD layer may be between about 0.5% atomic and 5% atomic or, more specifically, between about 0.5% atomic and 5% atomic or even between about 0.5% atomic and 5% atomic. The LLD layer may have a thickness of between about 3,000 Angstroms and 10,000 Angstroms.

These and other embodiments are described further below with reference to the figures.

### BRIEF DESCRIPTION OF THE DRAWINGS

FIGS. 1A-1D are various schematic representations of superconducting circuits, in accordance with some embodiments.

FIG. 2A-2B are two process flowchart examples corresponding to a method of forming a superconducting circuit shown in FIGS. 1B-1D, in accordance with some embodiments.

### DETAILED DESCRIPTION

In the following description, numerous specific details are set forth in order to provide a thorough understanding of the presented concepts. The presented concepts may be practiced without some or all of these specific details. In other instances, well known process operations have not been described in detail so as to not unnecessarily obscure the described concepts. While some concepts will be described in conjunction with the specific embodiments, it will be understood that these embodiments are not intended to be limiting.

### Introduction

As described above, many silicon containing dielectric materials, such as silicon oxide and silicon nitride, suffer from high loss tangent. Without being restricted to any particular theory, it is believed that the loss tangent is caused by various defects (such as dangling bonds, weak bonds, contaminants) formed during deposition of these layers. For example, when a silicon containing dielectric material is formed using silane, a small portion of hydrogen atoms may stay in the dielectric layer due to, for example, incomplete decomposition of silane. Some of these remaining hydrogen atoms may retain strong atomic bonds with silicon such that each of these hydrogen atoms is bonded only with one silicon atoms. Other remaining hydrogen atoms may have weak bonds, such that each of these hydrogen atoms may be weakly bonded to two or more silicon atoms. While the strong bonds do not create any major loss tangent concerns unless converted into weak bonds, the weak bonds may result in an unstable two-level system when the silicon containing material is subjected to high frequencies. Specifically, a hydrogen atom having multiple weak bonds bond may randomly change its state and form, for example, other weak bonds with other silicon atoms. In other words, weak bonds can be easily changed when the silicon containing material is subjected to the operating conditions with unpredictable outcomes. Furthermore, the process of changing weak bonds may continue indefinitely and change with changes in processing conditions. Overall, deposition defects in silicon containing dielectric materials create very unstable performance characteristics in LLD layers used for superconducting circuits.

It has been found that fluorine passivation may neutralize defects and, more specifically, defects' contribution to loss tangent due. Without being restricted to any particular theory, it is believed that when fluorine is added to various silicon containing dielectric materials, fluorine binds to dangling bonds of silicon atoms and, in some instances, displaces hydrogen. Fluorine has stronger bonds with silicon than hydrogen and does not create two level systems even if there is another dangling silicon bond nearby. Experimental results have shown that the defect density in silicon oxide layers doped with fluorine have decreased by more than 10-fold in comparison to similar layers that have not been doped. The only comparable results were achieved by annealing un-doped layers at temperatures of 800° C. or higher. However, such high temperatures may be damaging to surrounding circuits. Furthermore, annealing at lower temperatures (e.g., at 550° C.) produced only marginal improvements in defect density. As such, doping silicon oxide with fluorine appear to yield unexpected results highly desirable for superconducting applications.

Some conventional approaches focused on minimizing bulk defects during deposition by, for example, changing processing conditions or by healing defects at surfaces. For example, using higher deposition temperatures and/or slower deposition rates (e.g., due to the lower concentration of silicon containing precursor) may result in less dangling bonds in the deposition materials. However, high deposition temperatures may result in silicide formation at the interface of the dielectric material and metal electrodes, which is not desirable. The slower deposition rates increase the overall processing times and may not be suitable for bulky structures, such as LLD layers. In general, fluorine containing low loss dielectric layers for superconducting circuits and, in particular, for low temperature superconducting circuits have not been explored.

Superconducting circuits described herein include silicon containing LLD layers (e.g., silicon nitride or silicon oxide) containing fluorine, which passivates dangling bonds of silicon atoms in the layers. In order to achieve uniform passivation (e.g., uniform distribution of fluorine within the LLD layer), fluorine may be introduced while forming the LLD layer. Specifically, a fluorine containing precursor may be used together (e.g., flowed simultaneously or intermittently pulsed into a deposition chamber) with a silicon containing precursor during CVD, ALD, or any other suitable deposition technique. Furthermore, some fluorine distribution with the formed LLD layer may be performed by post-deposition annealing. Annealing may also help with binding fluorine to silicon and replace dangling bonds. In some embodiments, the LLD layer may be formed as a stack of many thin sublayers, and each sublayer may be subjected to individual fluorine passivation. The thickness of these sublayers may be sufficiently small to ensure fluorine penetration through the entire thickness of the sublayer.

The amount of fluorine added into a silicon based dielectric material may depend on the type and composition of this material as well as on processing conditions used to form the material. The concentration of fluorine in the LLD layer may be between about 0.5% atomic and 5% atomic or, more specifically, between about 0.5% atomic and 5% atomic or even between about 0.5% atomic and 5% atomic. Fluorine passivated dielectric layers may be used in microwave waveguides or wiring for high frequency signals in superconducting circuits. The reduction in loss tangent allows higher frequency operation (e.g., faster clock speed) and improves timing margin in clocked circuits. Furthermore, this reduction in loss tangent lengthens the time a quantum state maintains its quantum coherence in quantum computing application.

### Examples of Superconducting Circuits

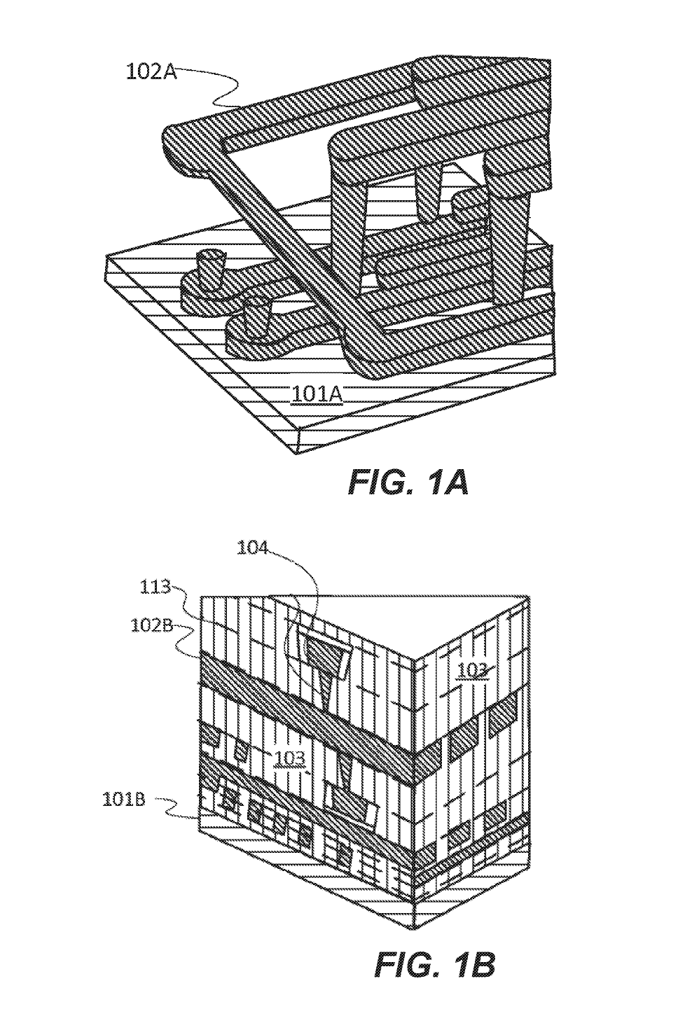

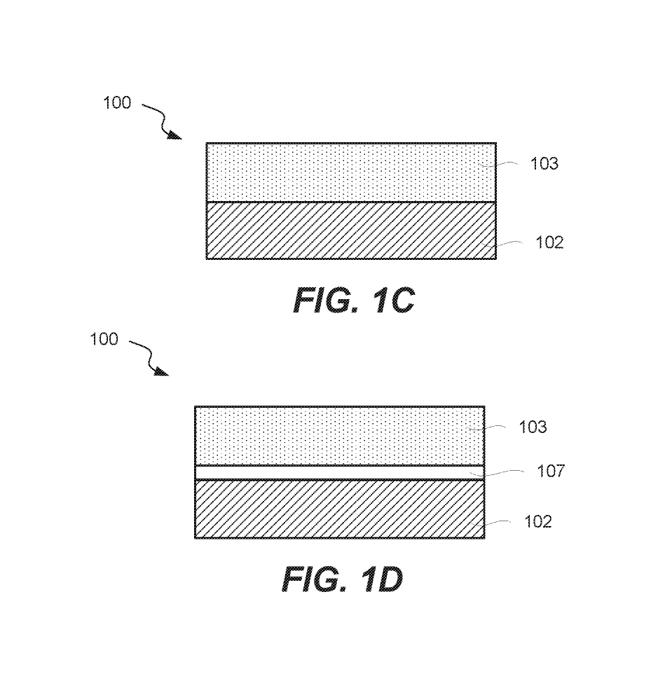

FIGS. 1A and 1B conceptually illustrate metal layers and LLD layers in superconducting circuits. Specifically, FIG. 1A illustrates multiple metal layers, which may be also referred to as interconnects, without showing an LLD layer. This figure is presented simply to better visualize the three-dimensional network of metal layer 102A built up on substrate 101A. Substrate 101A may have other LLD layers and conductive structures below those shown. Metal layer 102A may be formed by forming a blanket conductive layer followed by etching to form a separate conductive path. In superconducting microwave devices, metal layer 102A may be formed from any suitable superconducting material, such as aluminum (Al), niobium (Nb), niobium alloys, niobium nitride, ceramic superconductors, or organic superconductors.

FIG. 1B is a schematic cutaway view of several interconnect and device layers. Here, LLD layer 103 is shown disposed between different structures. Heavy dotted lines 113 delineate the separately formed layers. The illustrated structures include some metal layer 102B, and also some components 104 (e.g., transistors, capacitors, switches, resistors, resonators; in a superconducting device, the components may include Josephson junctions). In some embodiments, electrodes 102B are parts of Josephson junctions.

FIGS. 1C and 1D illustrates schematic representations of two examples of superconducting circuit 100. Superconducting circuit 100 includes metal layer 102. Metal layer 102 may be a part of Josephson junction, for example. Superconducting circuit 100 may also include LLD layer 103 disposed over metal layer 102. In some embodiments, LLD layer 103 may directly interface metal layer 102 as, for example, shown in FIG. 1C. Alternatively, LLD layer 103 may be separated from metal layer 102 by barrier layer 107 as, for example, shown in FIG. 1D. Barrier layer 107 may help to protect metal layer 102 from reacting with silicon of LLD layer 103 and forming silicides at the interface of LLD layer 103 and metal layer 102. Barrier layer 107 may be, for example, a nitride layer (e.g., a metal nitride of a metal forming metal layer 102).

LLD layer 103 may include one of silicon nitride or silicon oxide. In some embodiments, LLD layer 103 includes silicon oxide. LLD layer 103 may also include fluorine evenly distributed throughout LLD layer 103. For purposes of this disclosure, the term “evenly distributed” is defined as a variability of the fluorine concentration being less than 20% throughout the entire volume of LLD layer 103. The concentration of fluorine in LLD layer 103 may be between about 0.5% atomic and 5% atomic or, more specifically, between about 0.5% atomic and 5% atomic or even between about 0.5% atomic and 5% atomic. In general, enough fluorine is needed to passivate dangling substantial amount of bonds defects in LLD layer 103. However, excessive amounts will introduce different types of defects and contribute to more loss.

LLD layer 103 may have a thickness of between about 3,000 Angstroms and 10,000 Angstroms. It should be noted that surface treatment of LLD layer 103 (as a complete layer) when LLD layer 103 has this thickness would not provide sufficiently uniform distribution of fluorine within the layer. At the same time, uniform distribution of fluorine within LLD layer 103 is essential for lowering loss tangent. As such, many fluorine treatment approaches of dielectric layers would not be applicable for LLD layer 103 used for superconducting applications. Furthermore, some conventional fluorination treatment methods, such as plasma-based methods, may be damaging to the surface and create new defects.

### Examples of Forming Superconducting Circuits

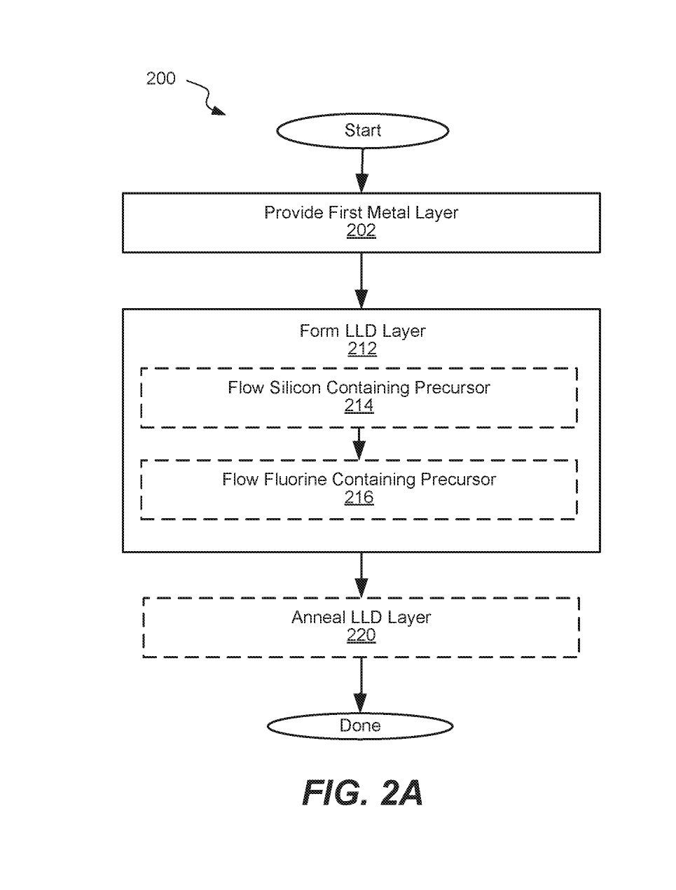

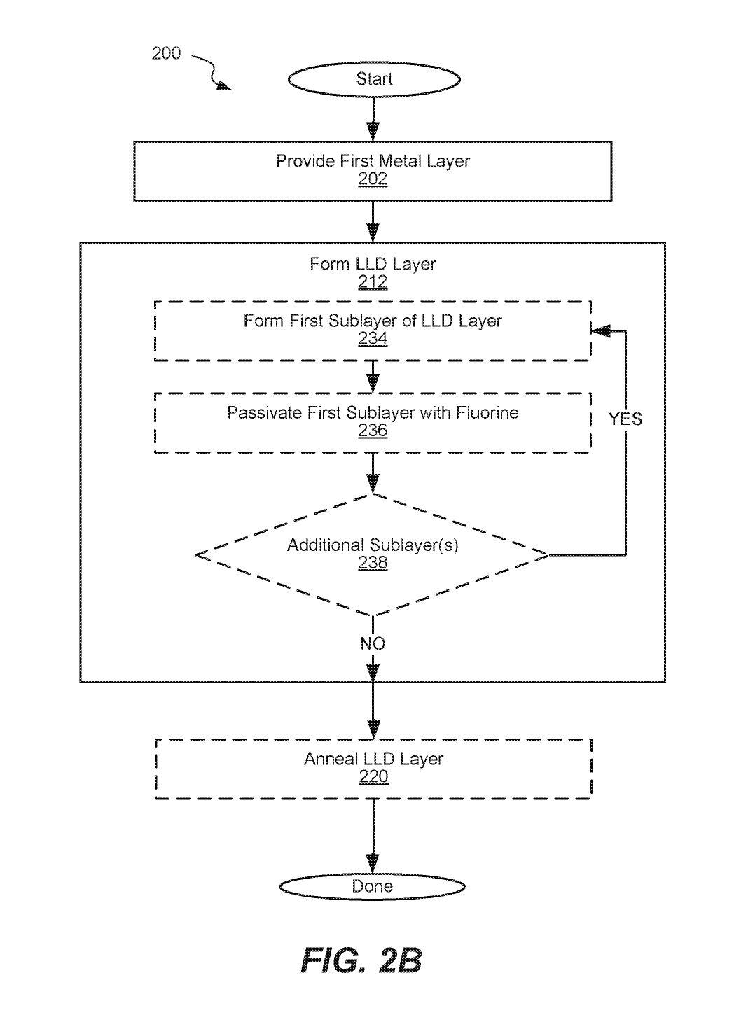

FIGS. 2A and 2B are process flowcharts corresponding to different examples of method 200 of forming a superconducting circuit, in accordance with some embodiments. Various examples of superconducting circuit are described above with reference to FIGS. 1C-1D. Method 200 may commence with providing a metal layer during operation 202. The metal layer may be a part of Josephson junction, for example. The metal layer may include niobium, for example. In some embodiments, the metal layer may have a barrier layer disposed on the top of the barrier layer and protect the barrier layer during formation of an LLD layer. The barrier layer may be formed, for example, by converting a portion of the metal layer into a nitride.

Method 200 may proceed with forming a LLD layer during operation 212. The LLD layer is formed over the metal layer. In some embodiments, the LLD layer is formed directly on the LLD layer, e.g., as shown in FIG. 1C. Alternatively, a barrier layer may be formed on the metal layer prior to forming the LLD layer, e.g., as shown in FIG. 1D. For example, a metal layer may be exposed to a nitrogen containing environment to convert a portion of the metal layer into a metal nitride barrier layer.

In some embodiments, the LLD layer is formed using CVD. CVD is relatively fast and inexpensive method of forming silicon containing dielectric layers. However, as was described above, conventional CVD produces a silicon containing dielectric with many defects that are not suitable for superconducting applications because of a substantial level of loss tangent. Contrary to the conventional CVD, operation 212 produces an LLD layer containing fluorine. Fluorine passivates defects cites within the LLD layer thereby decreasing the loss tangent. Fluorine may be evenly distributed within the LLD layer. Besides fluorine, the LLD layer also includes one of silicon nitride or silicon oxide. Various examples of LLD layers are described above with reference to FIGS. 1C and 1D.

In some embodiments, operation 212 (forming the LLD layer) involves flowing a silicon containing precursor into a deposition chamber during optional operation 214. The silicon containing precursor may include one of disilane or trisilane or more generally any linear hydro-silicon having a general formula of Si_{N}H_{2N+2} where N≧2 Without being restricted to any particular theory, it is believed that using disilane or trisilane (or higher order silanes), which already have silicon-silicon bonds form at the precursor level, yields a dielectric material with less defects than, for example, when mono-silane is used. Specifically, disilane or trisilane (or higher order silanes) already have strong silicon-silicon bonds, which are believed to be preserved when depositing the dielectric materials. Furthermore, using disilane or trisilane (or higher order silanes) allows lowering the deposition temperature in comparison, for example, to forming a LLD layer from mono-silane.

Furthermore, operation 212 (forming the LLD layer) may involve flowing a fluorine containing precursor into the deposition chamber during optional operation 216. The fluorine containing precursor may include one of nitrogen trifluoride, hydrogen fluoride, xenon difluoride, or silicon tetrafluoride. In some embodiments, nitrogen trifluoride may be used since xenon difluoride etches silicon at high rates.

In some embodiments, the fluorine containing precursor may be flowed continuously and together with the silicon containing precursor. More specifically, the silicon containing precursor may be flowed at a constant flow rate while forming the LLD layer, and the fluorine containing precursor may also be flowed at a constant flow rate while forming the LLD layer.

Alternatively, the silicon containing precursor may be flowed at a constant flow rate while forming the LLD layer, while the fluorine containing precursor may be flowed in a series of pulses while forming the LLD layer.

Furthermore, the silicon containing precursor and the fluorine containing precursor may be flowed in separate pulses. In other words, the silicon containing precursor may be flowed in one or more pulses (silicon pulses) during which the fluorine containing precursor is not flowed into the deposition chamber. The fluorine containing precursor may be flowed into the chamber during its own one or more pulses (fluorine pulses) during which the silicon containing precursor is not flowed into the deposition chamber. The fluorine pulses may alternate with the silicon pulses.

In some embodiments, CVD used during operation 212 may be PECVD. PECVD may have a faster deposition rate in comparison to similar CVD without plasma and may be performed at a lower processing temperature. Furthermore, PECVD may result in lower concentration of defects and may need less fluorine to achieve the same level of defects in the resulting LLD layer. Without being restricted to any particular theory, it is believed that plasma may help with breaking silicon-hydrogen bonds in a precursor. As a result, the deposited dielectric may have fewer silicon dangling bonds and, possibly, residual hydrogen.

As shown in FIG. 2B, operation 212 (forming the LLD layer) may involve first depositing a silicon containing sublayer of the LLD layer during optional operation 234 followed by fluorine passivation of that silicon containing sublayer during optional operation 236. These operations 234 and 236 may be repeated one or more times, as illustrated by decision block 238 in FIG. 2B. For example, operations 234 and 236 may be repeated until reaching a target thickness of the LLD layer. Each of the silicon containing sublayer formed during operation 234 may have a thickness of less than 500 Angstroms or even less than 100 Angstroms. At the same time, the thickness may be at least about 5 Angstroms or even at least about 10 Angstroms to ensure sufficient processing throughput and allowing forming the entire LLD layer is a practical number of cycles, each cycle including operation 234 and 236. In some embodiments, the LLD layer has a thickness of between about 3,000 Angstroms and 10,000 Angstroms.

Operation 234 may be similar to LLD layer deposition described above but performed without adding fluorine into silicon containing sublayers. Fluorine is later introduced into these sublayers during fluorine passivation.

The fluorine passivation during operation 236 may involve one of plasma treatment or thermal annealing. In some embodiments, the number of silicon dangling bonds decrease in the silicon containing layer while performing the fluorine treatment. Some defects created during the fluorine passivation of a sublayer may be cured with when a subsequent sublayer is formed. In some embodiments, a sublayer is thermally treated with nitrogen tri-fluoride.

In some embodiments, operation 212 (forming the LLD layer) is performed at a temperature of less than 525° C. or even at a temperature of less than 510° C. and even less than 500° C. Low deposition temperature may help with preventing silicide formation at the interface of the LLD layer and metal layer when, for example, a barrier layer is not used between the LLD layer and metal layer.

Method 200 may involve annealing of the LLD layer during optional operation 220. In some embodiments, annealing performed during this operation may be thermal annealing. For example, the LLD layer may be subjected to a temperature of between about 300° C. and 600° C. for between about 5 minutes and 60 minutes. Without being restricted to any particular theory, it is believed that annealing may help with more uniform distribution of fluorine within the LLD layer, in particular, when fluorine is introduced into previously formed silicon layers (as described above with reference to FIG. 2B). Furthermore, annealing may provide sufficient activation energy for fluorine to react with silicon and replace dangling bonds, for example.

### CONCLUSION

Although the foregoing concepts have been described in some detail for purposes of clarity of understanding, it will be apparent that certain changes and modifications may be practiced within the scope of the appended claims. It should be noted that there are many alternative ways of implementing the processes, systems, and apparatuses. Accordingly, the present embodiments are to be considered as illustrative and not restrictive.

What is claimed is:

1. A method of forming a superconducting circuit, the method comprising:
providing a metal layer,
wherein the metal layer is a part of Josephson junction; and
forming a low loss dielectric (LLD) layer over the metal layer using chemical vapor deposition (CVD),
wherein the low loss dielectric layer comprises one of silicon nitride or silicon oxide, and
wherein the low loss dielectric layer further comprises fluorine evenly distributed throughout the low loss dielectric layer.

2. The method of claim 1, wherein the low loss dielectric layer comprises silicon oxide.

3. The method of claim 1, wherein a concentration of fluorine in the low loss dielectric layer is between about 0.5% atomic and 5% atomic.

4. The method of claim 1, wherein forming the low loss dielectric layer comprises flowing a silicon containing precursor into a deposition chamber and flowing a fluorine containing precursor into deposition chamber at same time with the silicon containing precursor.

5. The method of claim 4, wherein the silicon containing precursor comprises one of disilane or trisilane.

6. The method of claim 4, wherein the fluorine containing precursor comprises one of nitrogen trifluoride, hydrogen fluoride, xenon difluoride, or silicon tetrafluoride.

7. The method of claim 4, wherein the chemical vapor deposition is a plasma enhanced chemical vapor deposition (PECVD).

8. The method of claim 4, wherein the silicon containing precursor is flowed at a constant flow rate while forming the low loss dielectric layer, and wherein the fluorine containing precursor is flowed at a constant flow rate while forming the low loss dielectric layer.

9. The method of claim 4, wherein the silicon containing precursor is flowed at a constant flow rate while forming the low loss dielectric layer, and wherein the fluorine containing precursor is flowed in a series of pulses while forming the low loss dielectric layer.

10. The method of claim 1, wherein forming the low loss dielectric layer comprising:
(a) depositing a silicon containing sublayer of the low loss dielectric layer;
(b) performing fluorine passivation of the silicon containing sublayer; and
(c) repeating (a) and (b) until reaching a target thickness of the low loss dielectric layer.

11. The method of claim 10, wherein each of the silicon containing sublayer has a thickness of less than 100 Angstroms.

12. The method of claim 10, wherein the fluorine passivation comprises one of plasma treatment or thermal annealing.

13. The method of claim 10, wherein a number of silicon dangling bonds decrease in the silicon containing layer while performing the fluorine passivation.

14. The method of claim 1, further comprising thermal annealing the low loss dielectric layer.

15. The method of claim 1, wherein forming the low loss dielectric layer is performed at a temperature of less than 525° C.

16. The method of claim 1, wherein the low loss dielectric layer has a thickness of between about 3,000 Angstroms and 10,000 Angstroms.

17. A superconducting circuit comprising:
a metal layer,
wherein the metal layer is a part of Josephson junction; and
a low loss dielectric layer disposed over the metal layer,
wherein the low loss dielectric layer comprises one of silicon nitride or silicon oxide, and
wherein the low loss dielectric layer further comprises fluorine evenly distributed throughout the low loss dielectric layer.

18. The superconducting circuit of claim 17, wherein a concentration of fluorine in the low loss dielectric layer is between about 0.5% atomic and 5% atomic.

19. The superconducting circuit of claim 17, wherein the low loss dielectric layer comprises silicon oxide.

20. The superconducting circuit of claim 17, wherein the low loss dielectric layer has a thickness of between about 3,000 Angstroms and 10,000 Angstroms.
